(19) United States
(12) Patent Application Publication
(10) Pub. No.: US 2024/0387448 A1
(43) Pub. Date: Nov. 21, 2024

(54) ROENTGEN INTEGRATED METROLOGY FOR HYBRID BONDING PROCESS CONTROL IN ULTRA HIGH 3D INTEGRATION

(71) Applicant: Tokyo Electron Limited, Tokyo (JP)

(72) Inventors: Francisco MACHUCA, Oakland, CA (US); James S. PAPANU, San Rafael, CA (US); Xinkang TIAN, Austin, TX (US); Arkalgud SITARAM, Albany, NY (US)

(73) Assignee: Tokyo Electron Limited, Tokyo (JP)

(21) Appl. No.: 18/419,733

(22) Filed: Jan. 23, 2024

Related U.S. Application Data
(60) Provisional application No. 63/466,480, filed on May 15, 2023.

(51) Int. Cl. H01L 23/00; G01N 23/04; G01N 23/083; G01N 23/18; H01L 21/66; H01L 21/67

(52) U.S. Cl. CPC H01L 24/80; G01N 23/04; G01N 23/083; G01N 23/18; H01L 21/67259; H01L 22/12; H01L 22/20; G01N 2223/6116; G01N 2223/646; H01L 2224/80125; H01L 2224/80895; H01L 2224/80896

(57) ABSTRACT

A hybrid bonding apparatus includes a hybrid bonder that has a bonder head and is configured to bond a first semiconductor structure to a second semiconductor structure via hybrid bonding. The hybrid bonding apparatus also includes an X-ray probe having an X-ray source and a detector. The bonder head is positioned in a measurement gap between the X-ray source and the detector or positioned in a measurement space opposite to both the X-ray source and the detector. The X-ray probe is configured to irradiate X-rays through the first semiconductor structure and the second semiconductor structure, in whole or in part, to measure relative positions of the first semiconductor structure and the second semiconductor structure. The hybrid bonder is configured to align the first semiconductor structure and the second semiconductor structure based on the relative positions of the first semiconductor structure and the second semiconductor structure.

### INCORPORATION BY REFERENCE

This present disclosure claims the benefit of U.S. Provisional Application No. 63/466,480, filed on May 15, 2023, which is incorporated herein by reference in its entirety.

### FIELD OF THE INVENTION

This disclosure relates to microelectronic devices including semiconductor devices, transistors, and integrated circuits, and methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire to continue to improve “power performance, area, cost” or PPAC by implementing three-dimensional integration strategies or “3DI”. Many of these strategies employ stacking, such as die to die, die to wafer, and wafer to wafer for 3DI of circuits, transistors, memory cells, and interconnections between them; introducing for the first time failure and reliability issues with fully vetted known good die. The purpose of this disclosure is to propose innovations that can address a leading contributor to expensive loss of known good die, by taking corrective actions during 3DI bonding.

### SUMMARY

The present disclosure relates to a hybrid bonding apparatus, a method of hybrid bonding, and a method of bonding inspection to procure known good die in post wafer finish processes during 3DI formation.

According to a first aspect of the disclosure, a method of hybrid bonding is provided. A first bonding surface of a first semiconductor structure is positioned at a first distance from a second bonding surface of a second semiconductor structure. The structure may refer to a whole or a fraction of the following: a die, a wafer, a set of stacked dies, or a set of stacked wafers, in any order for a single pair or multiple combinations of the same. The first bonding surface of the first semiconductor structure faces the second bonding surface of the second semiconductor structure. Relative positions of the first bonding surface and the second bonding surface at the first distance are measured via an X-ray probe. The first bonding surface and the second bonding surface are brought closer to a second distance that is smaller than the first distance. The relative positions of the first bonding surface and the second bonding surface at the second distance are again measured via the X-ray probe. Relative positions of the first semiconductor structure and the second semiconductor structure are adjusted based on X-ray measurements of the first bonding surface and the second bonding surface. The first bonding surface and the second bonding surface are then brought into physical contact. The first semiconductor structure and the second semiconductor structure are bonded via hybrid bonding, meaning, for example, direct copper to copper bond formation between first and second structures in question.

In some embodiments, a bonding interface between the first semiconductor structure and the second semiconductor structure is analyzed via the X-ray probe after the hybrid bonding.

In some embodiments, defect analysis is performed via the X-ray probe, of at least one interface defect selected from the group consisting of a void, a gap, delamination, foreign material, aberrant copper pad size, missing pad, or misalignment.

In some embodiments, adjusting the relative positions of the first semiconductor structure and the second semiconductor structure includes removing out-of-plane tilt based on the relative positions of the first bonding surface and the second bonding surface at the first distance and at the second distance so that the first bonding surface and the second bonding surface are parallel to each other.

In some embodiments, at least one in-plane misalignment selected from the group consisting of a translational misalignment and a rotational misalignment are removed.

In some embodiments, after removing the out-of-plane tilt, the relative positions of the first bonding surface and the second bonding surface at the second distance are re-measured via the X-ray probe. Then the at least one in-plane misalignment is removed based on the re-measuring.

In some embodiments, after removing the out-of-plane tilt misalignment, the first bonding surface and the second bonding surface are brought closer to a third distance that is smaller than the second distance. The relative positions of the first bonding surface and the second bonding surface at the third distance are measured via the X-ray probe. Then the at least one in-plane misalignment is removed based on the relative positions of the first bonding surface and the second bonding surface at the third distance.

In some embodiments, the relative positions of the first bonding surface and the second bonding surface are measured via the X-ray probe in real time.

In some embodiments, the first bonding surface and the second bonding surface are measured via the X-ray probe, and a relative bow/warp of the first bonding surface and the second bonding surface is detected and removed by applying a correction from a group consisting of barrel or pin cushion distortion.

In some embodiments, the relative positions of the first bonding surface and the second bonding surface are measured via the X-ray probe in real time.

In some embodiments, (a) the first bonding surface and the second bonding surface are brought closer to a smaller distance, and (b) the relative positions of the first semiconductor structure and the second semiconductor structure are adjusted, based on real-time X-ray images, or by X-ray detection via an X-ray non-imaging system of the first bonding surface and the second bonding surface at the smaller distance. (a) and (b) are repeated until the first bonding surface and the second bonding surface are brought into physical contact.

In some embodiments, the X-ray probe is configured to irradiate X-rays that penetrate through the first semiconductor structure and the second semiconductor structure, in whole or in part.

In some embodiments, the X-ray probe includes at least one selected from the group consisting of an X-ray imaging system and an X-ray non-imaging system. The X-ray imaging system is configured to generate images of the first bonding surface and the second bonding surface via at least one mechanism selected from the group consisting of scintillation, direct imaging of X-rays, X-ray absorption imaging, X-ray phase contrast imaging, X-ray interferometric fringe difference imaging, and small angle scatter dark field imaging. The X-ray non-imaging system is configured to generate an X-ray measurement signal via at least one mechanism selected from the group consisting of X-ray diffraction, X-ray absorption, small angle X-ray scatter (SAXS), wide angle X-ray scatter (WAXS), near-edge X-ray absorption fine structure analysis (NEXAFS), X-ray near edge absorption spectroscopy (XANES), total external reflectance X-ray fluorescence (TXRF), X-ray K-edge subtraction, X-ray standing wave analysis, and X-ray reflectivity

In some embodiments, an X-ray non-imaging system is configured to generate an X-ray measurement signal of the first bonding surface and the second bonding surface via at least one mechanism selected from the group of X-ray reflectivity, X-ray refraction, X-ray small-angle scatter, X-ray wide-angle scatter, X-ray absorption, X-ray absorption near edge, X-ray energy fine structure, X-ray total external reflection fluorescence, X-ray fluorescence, X-ray elastic or inelastic scattering energy analysis, X-ray standing wave, and X-ray diffraction.

In some embodiments, the second semiconductor structure is loaded and aligned into a measurement gap between an X-ray source of the X-ray probe and a detector of the X-ray probe.

In some embodiments, the second semiconductor structure is loaded and aligned into a space opposite the measurement system. The X-ray source and the X-ray probe, opposite the wafer, may also include X-ray optics, X-ray filters, X-ray collimators, X-ray crystal gratings, X-ray Sollier Plates, X-ray Zone plates, or other X-ray guiding components such as mirrors, gratings, polychromators, monochromators, diffractive lenses of any type, energy analyzers, and in general, a detector of the X-ray measurement system.

In some embodiments, the first semiconductor structure is attached to a bonder head of a hybrid bonder. The first semiconductor structure and the second semiconductor structure are aligned with alignment marks via an electromagnetic radiation other than X-rays.

In some embodiments, the first semiconductor structure includes a die, a wafer, a plurality of stacked dies or a plurality of stacked thinned wafers. The second semiconductor structure may include a die or a wafer.

In some embodiments, the first semiconductor structure includes two dies, or two wafers, double the plurality of stacked die or double the plurality of stacked thinned wafers, both offset laterally from the second semiconductor structure comprised of a die or a wafer, the second structure connected overhead, or vice versa, forming a bridge between the first semiconductor structures.

According to a second aspect of the disclosure, a method of bonding inspection is provided. A bonded structure, which includes a first semiconductor structure and a second semiconductor structure bonded to each other via a bonding interface, is provided. The bonded structure is irradiated with X-rays that are configured to penetrate through the bonded structure in whole or in part. An X-ray image or X-ray signal of the bonding interface is generated via at least one mechanism selected from the group consisting of scintillation, X-ray absorption mapping, phase contrast, or dark-field small angle scatter.

In some embodiments, defect analysis is performed, with the X-ray image or X-ray signal of the bonding interface, of at least one interface defect selected from the group consisting of a void, a gap, delamination, foreign material, aberrant copper pad size, missing pad, and misalignment.

According to a third aspect of the disclosure, a hybrid bonding apparatus is provided. The hybrid bonding apparatus includes a hybrid bonder that has a bonder head and is configured to bond a first semiconductor structure to a second semiconductor structure via hybrid bonding. The hybrid bonding apparatus also includes an X-ray probe having an X-ray source and a detector. The bonder head is positioned in a measurement gap between the X-ray source and the detector, or is disposed opposite the measurement system in reflection mode, or positioned in a measurement space opposite to both the X-ray source and the detector. The X-ray probe is configured to irradiate X-rays that penetrate through the first semiconductor structure and the second semiconductor structure, in whole or in part, to measure relative positions of the first semiconductor structure and the second semiconductor structure. The hybrid bonder is configured to align the first semiconductor structure and the second semiconductor structure based on the relative positions of the first semiconductor structure and the second semiconductor structure.

In some embodiments, the hybrid bonding apparatus further includes an objective having a bent path of electromagnetic radiation between the objective and the detector.

In some embodiments, the objective further includes a bandpass filter.

In some embodiments, the objective further includes a tube lens or a relay lens.

In some embodiments, the hybrid bonding apparatus further includes a color center mitigation system including a least one color center mitigation device selected from the group consisted of DUV illumination, a UV LED, a laser-driven light source, an IR lamp, a thermal jacket with a conductive heater, and a thermal wire.

According to another aspect of the disclosure, a hybrid de-bonding apparatus is provided. The hybrid de-bonding apparatus includes a hybrid de-bonder that has a de-bonding mechanism and is configured to de-bond a first semiconductor structure from a second semiconductor structure (mechanically, chemically, thermally, hydrostatically, vibrationally, or electrostatically). The hybrid de-bonding apparatus also includes an X-ray probe having an X-ray source and a detector. The de-bonder mechanism is integrated with the X-ray probe and positioned in a measurement gap between the X-ray source and the detector, or is disposed opposite the measurement system in reflection mode. The X-ray probe is configured to irradiate X-rays that penetrate through the first semiconductor structure and the second semiconductor structure, in whole or in part, to measure relative positions of the first semiconductor structure and the second semiconductor structure, prior to debonding. The hybrid de-bonder is configured to allow measurement of the relative alignment quality between the first semiconductor structure and the second semiconductor structure based on the relative positions of the first semiconductor structure and the second semiconductor structure.

In some embodiments, the detector includes a scintillator.

In some embodiments, the hybrid bonding or de-bonding apparatus further includes an objective having a bent path of electromagnetic radiation between the scintillator and the UV-VIS light objective and the detector, to avoid transmission losses due to light optics color-center defect browning.

In some embodiments, the hybrid bonding or de-bonding apparatus further includes an objective having a straight path of electromagnetic radiation between the scintillator and the UV-VIS light objective and the detector, by integrating DUV-UV lighting to actively reverse color-center defect formation, avoiding transmission losses due to light optics browning. The color-center reversal light may be turned on when X-ray light is off at any interval, including in real-time asynchronous with the X-ray measurement.

In some embodiments, the hybrid bonding or de-bonding apparatus further includes an objective having a straight path of electromagnetic radiation between the scintillator and the UV-VIS light objective and the detector, by integrating a thermal or optical heater to actively reverse color-center defect formation, avoiding transmission losses due to light optics browning. The color-center reversal energy is supplied thermally to the objective and lens holders and may be kept on continuously or periodically to recover optical transmission.

In some embodiments, the X-rays are configured to be substantially collimated with a divergence angle of smaller than 10 mRad.

In some embodiments, the detector includes a Peltier (thermoelectric) cooled X-ray detector, X-ray Flat Panel Detector, avalanche photodiode, photomultiplier tube, or other direct or indirect means for conversion of X-rays to electrical signal.

In some embodiments, the X-ray source is spatially coherent and includes at least one of a single monocapillary, a single polycapillary, a 1D or 2D array of monocapillaries, a 1D or 2D array of polycapilliaries, a 1D or 2D array of X-ray spots, a 1D or 2D array of laser spots focused onto a stream of liquid anodes or array of liquid anodes, a 1D or 2D array of micropatterned carbon nanotubes (CNTs) interacting with a metal target to form an array of X-ray spots, a 1D or 2D array of electron emitters matched to an array of solid or liquid metal anodes to form a 1D or 2D array of X-ray spots, a dispenser cathode large area electron emitter or a cold field large area electron emitter or a photocathode large area electron emitter focused onto a 1D or 2D array of solid or liquid metal anodes to form a 1D or 2D array of X-ray spots. A moncapillary or policapillary is of the focusing or collimating type.

In some embodiments, the X-ray source is spatially coherent and includes at least one of a single monocapillary, a single polycapillary, a 1D or 2D array of monocapillaries, a 1D or 2D array of polycapilliaries, a 1D or 2D array of X-ray spots, a 1D or 2D array of laser spots focused onto a stream of liquid anodes or array of liquid anodes, a 1D or 2D array of micropatterned carbon nanotubes (CNTs) interacting with a metal target to form an array of X-ray spots, a 1D or 2D array of electron emitters matched to an array of solid or liquid metal anodes to form a 1D or 2D array of X-ray spots, a dispenser cathode large area electron emitter or a cold field large area electron emitter or a photocathode large area electron emitter focused onto a 1D or 2D array of solid or liquid metal anodes to form a 1D or 2D array of X-ray spots. A moncapillary or policapillary is of the focusing or collimating type.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A shows a perspective view of a hybrid bonding apparatus in accordance with one embodiment of the present disclosure.

FIG. 1B shows a schematic of a hybrid bonding apparatus in accordance with one embodiment of the present disclosure.

FIG. 2 shows a flow chart of a process for hybrid bonding, in accordance with one embodiment of the present disclosure.

FIGS. 3A, 3B, 3C, 3D, 3E and 3F show cross-sectional views of two semiconductor structures at various intermediate steps of hybrid bonding, in accordance with some embodiments of the present disclosure.

FIG. 4 shows a flow chart of a process for hybrid bonding, in accordance with another embodiment of the present disclosure.

FIG. 5A shows a schematic of a bonded structure in conventional technologies.

FIG. 5B shows a schematic of a bonded structure in accordance with one embodiment of the present disclosure.

FIG. 6 shows a flow chart of a process for bonding inspection, in accordance with one embodiment of the present disclosure.

FIG. 7A shows a schematic of bonding inspection, in accordance with one embodiment of the present disclosure.

FIG. 7B shows a schematic of a bonded structure, in accordance with one embodiment of the present disclosure.

FIGS. 7C and 7D show cross-sectional views of a bonded structure, in accordance with some embodiments of the present disclosure.

FIG. 8A shows a schematic of bonding inspection, in accordance with another embodiment of the present disclosure.

FIG. 8B shows a schematic of a bonded structure, in accordance with another embodiment of the present disclosure.

FIGS. 8C and 8D show cross-sectional views of a bonded structure, in accordance with some embodiments of the present disclosure.

FIG. 9A shows a schematic of bonding inspection, in accordance with yet another embodiment of the present disclosure.

FIG. 9B shows a schematic of a bonded structure, in accordance with yet another embodiment of the present disclosure.

FIGS. 9C and 9D show cross-sectional views of a bonded structure, in accordance with some embodiments of the present disclosure.

FIG. 10A shows a schematic of bonding inspection, in accordance with yet another embodiment of the present disclosure.

FIG. 10B shows a schematic of a bonded structure, in accordance with yet another embodiment of the present disclosure.

FIGS. 10C and 10D show cross-sectional views of a bonded structure, in accordance with some embodiments of the present disclosure.

FIG. 11 shows a cross-sectional view of a bonded structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

3D integration, i.e. the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, where the same lithographic critical dimension (CD) could be applied throughout the structure without loss of performance, application to random logic designs is substantially more difficult. This is because the CD generally differs between the VLSI application processor block and the other blocks, such as memory, I/O, communication blocks, power, ground, etc. Therefore, 3D integration for logic chips, such as CPUs (central processing unit), GPUs (graphics processing unit), AI-XPUs (AI general processing unit), TPUs (tensor flow processing unit), XPUs (generalized processing unit), FPGAs (field programmable gate array), SoCs (systems on a chip), etc. require a chiplet approach wherein each functional block comprises a functional die or chip of a given CD node. This application-specific approach along with 3DI achieves Power, Performance, Area, and Cost (PPAC) improvement by utilizing higher efficiency/yield nodes for I/O, power, communication, and other common chip functions (e.g. security/encryption, Bluetooth, wi-fi, etc.), and reserves the leading-edge node for the most speed-critical components.

Power, Performance, Area, and Cost (PPAC) improvements and Moore's Law's logarithmic performance increases in semiconductor devices have historically progressed primarily through aggressive doubling of transistor count every 18 months enabled by dimensional shrink without regard to functional chip type or the proper management of power scaling and heat dissipation. In the past two decades, as the industry has moved away from fully integrated large silicon area systems on chip (SoCs), it has become clear that continual improvement in semiconductor devices comes via optimizing PPAC at the system integration level through advanced packaging technologies. These technologies enable different functional chip types (“chiplets”) to be integrated into a single package and/or memory chips to be stacked vertically along with controller devices. The advantages include, but are not limited to, i) integration of multiple high bandwidth memory (HBM) die creating parallel channels of high bitrate access to memory; ii) latest EUV lithography node CPU/XPU's to maximize LSI speed and bandwidth (such as SRAM stacked on the application processor (AP) to minimize latency and decrease drive voltage/power requirements; iii) independent die for I/O control and communication protocols off chip which can be fabricated with less expensive lithography tools and can actually have improved electrical performance such as minimizing unwanted impedance/resistance caused by over-scaling; iv) smaller die sizes to maximize yield per wafer; v) increased I/O density, and vi) backside power distribution schemes to separate line widths of ower delivery and ground from LSI digital logic.

Two key packaging technology trends essential to meet the industry's needs for further disaggregation and increased I/O density are vertical or 3D integration (3DI) and hybrid bonding (HB). In hybrid bonding, copper electrical connections and dielectric insulating materials on singulated die or full wafers can be bonded face-to-face onto substrate wafers, referred to as die-to-wafer (D2 W) and wafer-to-wafer (W2 W) hybrid bonding, respectively. After bonding, the substrate wafers are then singulated to produce the final packaged modules.

Precise alignment/placement of die or full wafer(s) to the substrate wafer is critical for high yield. Furthermore, metrology to assess the bonding interface quality (e.g. for being void-free, delamination-free) is needed for high productivity and utilization of the known good die/wafers. This metrology also needs to enable corrections and recovery, preferably real-time, of the bonding tool processes and hardware to ensure higher yield, by minimizing waste of known good die. The techniques described herein provide precise alignment and bonding quality assessment metrology.

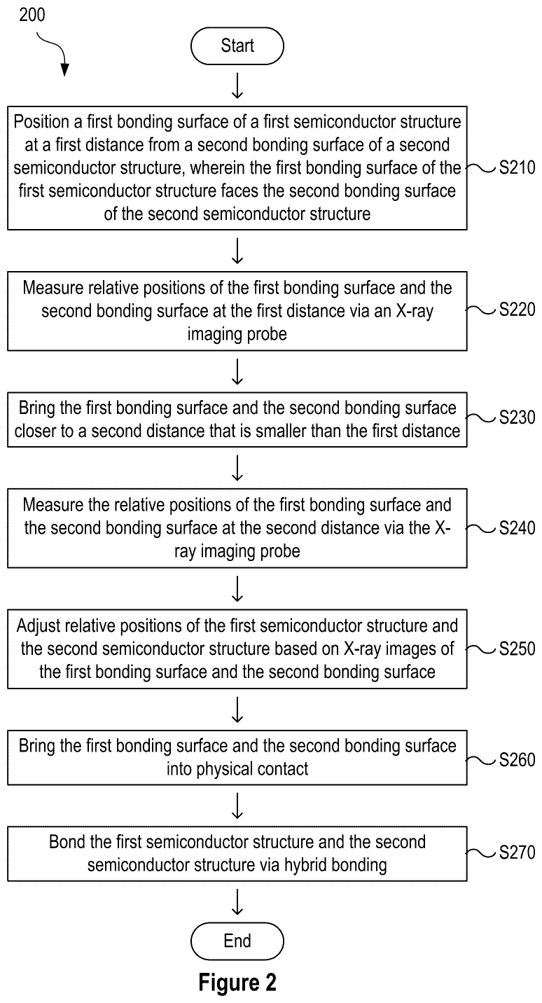

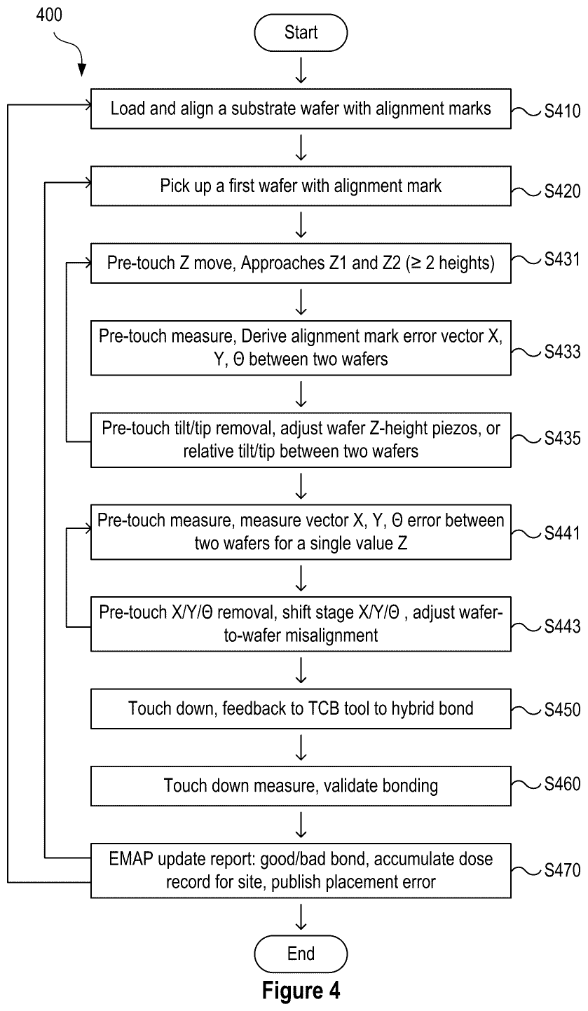

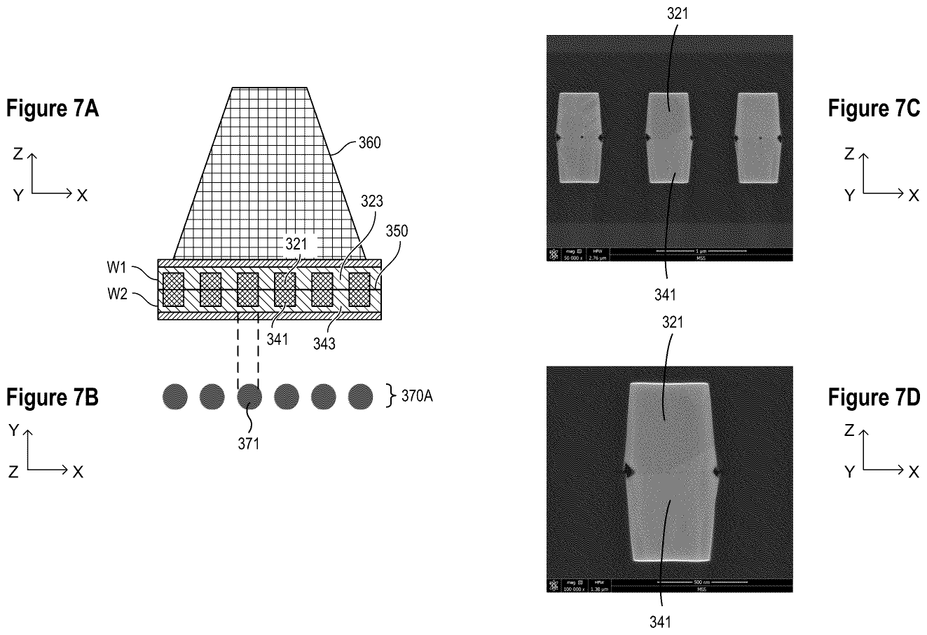

Ultra vertical 3DI stacking presents several unique challenges. Alignment and registry between layers need to be maintained without global registry. For instance, individual die-to-wafer, die-to-die, or in some cases a multitude of stacked thinned wafers or stacked die, require a deeply penetrating metrology technique to reference all the stacked die and metal layers with sufficient resolution to remove x, y, θ misalignments, targeting placement accuracies of less than ±60 nm. Techniques herein provide a device and solution to supply the critical feedback measurements to the 3DI hybrid bonder to optimize alignment; from die (wafer) pre-touch down to die (wafer) touch down and post hybrid bonding. In FIGS. 2 and 4, embodiments of the overall alignment strategy are summarized from die pick and place through measurement feedback and validation. To maximize 3DI potential, solder joints or micro-bumps in conventional technologies can be completely replaced and connected via RDL (redistribution lines) using direct Cu-to-Cu pad contacts and Cu pads to RDL line contacts. Once all die (wafers) are properly aligned and registered in the x, y, θ axes within the layer-to-layer placement accuracy, the second challenge is to inspect all electrical contacts to ensure complete and void-free bonding (see e.g. FIGS. 7A-7D). Currently, there is no solution for the simultaneous penetration and metrology of a multiplicity of die and/or substrates, their alignment/registry to each other via a wafer datum reference, and a verification of the quality of the hybrid bond between pads or between a pad and an RDL line. Representative data for alignment and interface voiding are shown in FIGS. 7A-7D, 8A-8D, 9A-9D, 10A-10D, and 11.

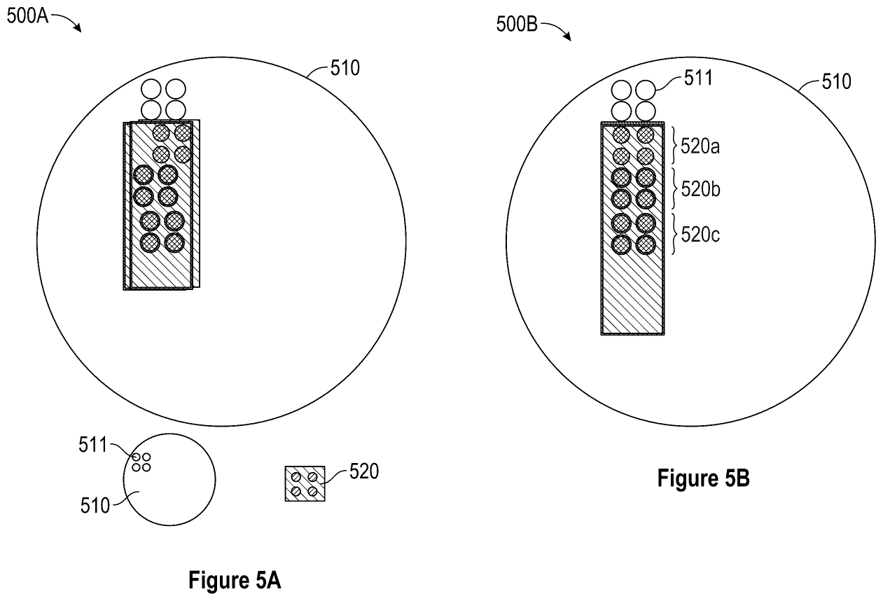

Aspects of the present disclosure relate to a real-time X-ray probe to register a multitude of die to a wafer or substrate, or a multitude of thinned wafers or stacked die on a substrate wafer or film frame to make high stacks of hybrid bonded devices. Techniques herein include pre-bonding inspection and metrology and post-bonding verification, and defect inspection. Methods used to perform corrective alignment can be based on computational X-ray metrology to locate, use automated machine judgement, and automatically remove shift and rotations of a die (wafer) relative to the underlying wafer or substrate. The method enables bonding of the first die to a substrate, and every subsequent die to die without loss of alignment through the 3DI stack (see e.g. FIGS. 5A and 5B).

Techniques herein include an inspection method of every metal-to-metal contact for the purpose of inspecting for voids, gaps, foreign material, aberrant sized pads, and missing pads among the Cu pads, or defects in the purely dielectric interfaces commonly used in hybrid bonding (see e.g. FIGS. 7A-7D, 8A-8D, 9A-9D and 10A-10D). This hybrid bonding step can be performed in tandem with the verification step for alignment.

Aspects of the present disclosure relate to an apparatus that can be integrated directly into one or more hybrid bonding heads of a hybrid bonding or de-bonder tool (bonder or de-bonder) for the purpose of real-time alignment feedback to the bonder prior to touching down; the metal-to-metal and dielectric-to-dielectric interfaces can hover without touching to avoid improper bond initiation for interfacial bond formation until the probe head parameters are optimal (geometry/curvature settings, temperature setting, pressure setting, point of contact initiation). In a de-bonder, real-time misalignment is characterized and a debonding corrective path is taken during 3DI. Notwithstanding, techniques herein can be practiced in a standalone module, integrated metrology (IM) module, or tool for post inspection verification of both alignment accuracy across all stacked die on the substrate, as well as full wafer inspection of all bonded pads for voids, gaps, foreign material, aberrant sized pads, and missing pads. In the latter, the technique is fully automated without operator intervention and with minimized or eliminated flawed characterizations, utilizing machine learning frameworks to compare like regions to like regions for bonding quality.

Techniques herein provide an integration of multi-die alignment capability, which uses X-ray probing, data feedback and feedforward control, with hybrid bonders and de-bonders. This will keep a die-to-wafer bonder from driving blind when using optical overlay techniques, or infrared light, neither of which can penetrate metal. Additionally, real-time die corrections can be made prior to placing the die and touching down for the first time. Moreover, the use of deeply penetrating X-rays allows the alignment to be repeated multiple times, to minimize overall tolerance stackup errors because each Si die can be aligned to a singular datum plane, namely the wafer or substrate. This is because X-rays are transmissive and will pass through all the die and all the metal layers and structures to form a contrast image which will be called a hybrid bond 2D map hereinafter.

Techniques herein provide an integration of the X-ray probe with the die/wafer bonder head for the first time, which will mitigate bad die loss and remove the need for costly re-work of die (i.e. the de-bonder use case.) The X-ray probe can provide feedback for alignment before touch-down, giving the hybrid bonder machine intelligence to adjust X, Y and θ errors between die and wafer. In the future, for multi-head parallelism, each die bonder head can have an independent capillary X-ray source and X, Y, 0 movement to adjust the respective die with respect to a fixed substrate wafer simultaneously, creating a throughput speedup.

Techniques herein enable the ability to detect voids, gaps, foreign material, aberrant sized pads, and missing pads using the X-ray spatial phase coherence, for metal and/or dielectric. The X-rays can undergo total external reflection in recessed Cu voids at interfaces, or roll-off dielectric induced void errors, or other gaps formed by incomplete hybrid bonding, and can be detected as focused intensity or an X-ray highlight in the hybrid bond 2D map. These gaps cannot be detected by conventional mass absorption X-ray contrast, which is the main contrast mechanism found in regular 2D/2.5D X-ray imaging or 3D computed tomography (CT) machines.

According to aspects of the present disclosure, the X-ray source may leverage pulse width modulation (PWM) schemes for turning power on/off to control the local total ionizing dose deposited in each die. The trade-off between sufficient radiation to image and that deposited to safely operate memory devices can be made, wherein higher energies interact little with the device but can generate significantly enhanced dielectric contrast. PWM forms a high precision dose to meter, allowing subsequent dose-based reporting and chip certification strategies. For example, for 1 million on/off cycles (50% duty cycle) equal to 10 Rads of total exposure dose (a limit for HBM memory), each on/off cycle allows 10 μRads of dose control. For a duty cycle below 50%, such as a 1% duty cycle, a 0.1 μRad dose control accuracy can be achieved. A digital X-ray source dose can be quantified using a radiation sensor every hour or day to maintain calibration. A hybrid bonder can include a dose history certification and dose metering data during production. An exposure map can be reported per wafer and output to the factory host. This would be highly advantageous, for example for chip applications in the aerospace, medical, automotive, and self-driving technologies, for QA/QC.

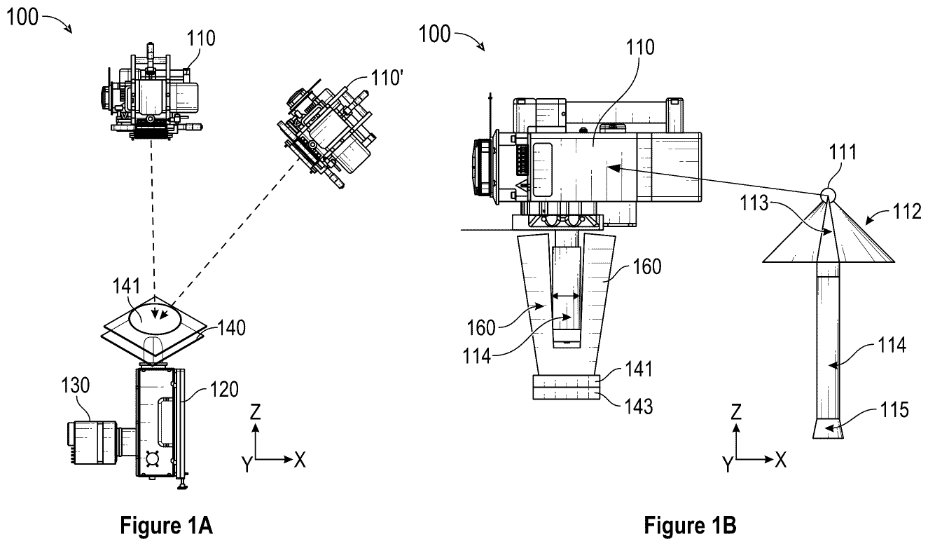

FIG. 1A shows a perspective view of a hybrid bonding apparatus 100, and FIG. 1B shows a schematic of the hybrid bonding apparatus 100, in accordance with some embodiments of the present disclosure. Note that not all parts of the hybrid bonding apparatus 100 are shown.

As illustrated, the hybrid bonding apparatus 100 includes an X-ray probe that includes an X-ray source 110, an optical train 120 and a detector 130. The X-ray source 110 and the optical train 120 are spaced apart from each other with a measurement gap 140 in between. The hybrid bonding apparatus 100 can also include a hybrid bonder that includes a bonder head 160 (or a bonding head) and is configured to bond a first semiconductor structure 141 to a second semiconductor structure 143 via hybrid bonding. The bonder head 160 is integrated, or not integrated, with the X-ray probe and positioned between the X-ray source 110 and the detector 130 during operation.

The X-ray probe is configured to irradiate X-rays that penetrate through the first semiconductor structure 141 and the second semiconductor structure 143, in whole or in part, to measure relative positions of the first semiconductor structure 141 and the second semiconductor structure 143. The hybrid bonder is configured to align the first semiconductor structure 141 and the second semiconductor structure 143 based on the relative positions of the first semiconductor structure 141 and the second semiconductor structure 143.

In a non-limiting example, the X-ray probe is an X-ray imaging system integrated to a die or wafer hybrid bonder (e.g. the hybrid bonder mentioned above) for the purpose of direct alignment control during hybrid bonding, followed by bond quality check, and quality map feedforward during 3DI hybrid bonding to subsequent steps (e.g. bonding finish or to begin next layer bonding operation). The X-ray probe can include the X-ray source 110, the measurement gap 140 which allows transmissive inspection or metrology of a die or wafer undergoing hybrid bonding with an ideal gap height in the range of 1 mm to 5 mm, and the optical train 120 and the detector 130 (e.g. a high spatial resolution X-ray detector) disposed opposite the X-ray source 110 and the measurement gap 140, for true submicron optical resolution. True optical resolution is defined as >2000 lines per mm at the corresponding value when the modulation transfer function (MTF) equals 10% of the maximum amplitude when measuring a well-calibrated set of lines and spaces (such as JIMA, NTT, or USAF metal targets).

The X-ray source 110 can include a point source 111 that is a broad-band X-ray module applying X-rays in a range of 0-120 keV, preferably 20-100 keV, preferably 30-90 keV, preferably 50-70 keV. The X-ray source 110 may have sufficient power in the energy range of 30-70 keV to create image contrast between a hybrid metal (e.g. Cu) and a background dielectric (e.g. Si, SiO₂, SiN, SiCN) using full field imaging. The X-ray source 110 may have a power of >150 W, with a divergence angle of <10 mRad, preferably <7 mRad, preferably <4 mRad, preferably <1 mRad, preferably <0.5 mRad, to ensure that no significant blur is induced in the measurement gap 140 which is about 0.5-7.5 mm, preferably about 1-5 mm, preferably about 2-4 mm wide.

In a preferred configuration, the X-ray source 110 is spatially-coherent and collimated with a top-hat X-ray intensity profile and has a FWHM beam size in a range of 5-25 mm, preferably 10-20 mm, preferably 13-17 mm. The X-ray source 110 can be turned on/off at >1 MHz repetition to enable pulse width modulation (PWM) control of dose deposited in a die or wafer. Spatial coherence can be achieved by passing X-rays through a collimator, diffracting from a crystal, or can be achieved at the source by a uniform repeating array of X-ray spots (e.g. laser driven plasma, array of field emitters spaced evenly, array of X-ray spots generated from a metal array of anodes), or can be achieved by a conventional source illuminating a phase shifting or phase absorbing X-ray grating, or using a synchrotron source. One of two modes of collimation can be used: monocapillary or polycapillary guiding as shown in FIG. 1B. That is, the point source 111 is configured to generate X-rays 112 which are uncollimated before a portion 113 of the X-rays 112 enters one or more capillaries 114. The one or more capillaries 114 can guide the portion 113 of the X-rays 112 such that the portion 113 of the X-rays 112 exits the one or more capillaries 114 as an X-ray beam 115 that includes substantially collimated X-rays having a divergence angle <10 mRad, preferably <7 mRad, preferably <4 mRad, preferably <1 mRad, preferably <0.5 mRad. Furthermore, the X-rays are substantially spatially coherent with a coherence length of 10 micrometers to 20 mm approximately, preferably 100 micrometers to 20 mm, preferably 1 mm to 20 mm, preferably 10 mm to 20 mm. An X-ray spatially coherent beam forms fringes with a delayed version of itself across a region that is about the size of the field being inspected.

In another configuration, the X-ray source 110 may be uncollimated, and shaped using high aspect ratio (HAR) tungsten pattern such as two pin holes separated at a distance or a single long hole through a tungsten block or another heavy atomic number metal plate. Alternatively, a plurality of metal plates forming a blade with many thin baffles may be used. The high aspect ratio (HAR, i.e. ratio of tungsten block height or thickness to hole diameter, or blade height to thickness) is >15:1, preferably >25:1, preferably >40:1, and preferably >50:1.

For image formation, the collimated or low-divergence X-rays (e.g. 113) passing through the capillary (e.g. 114) or HAR tungsten, penetrate through the die (e.g. 141) and the wafer (e.g. 143), both before touch-down and after touch-down, for example, to form a shadow projection of metal features that form the electrical connections in hybrid bonding, which will be further explained in FIGS. 7A-7D. The contrast image can be a 2D mass absorption map, phase contrast map, or small angle scatter i.e. dark field map of regions with no metal and those with varying degrees of metal overlap between die and wafer, or wafer and wafer.

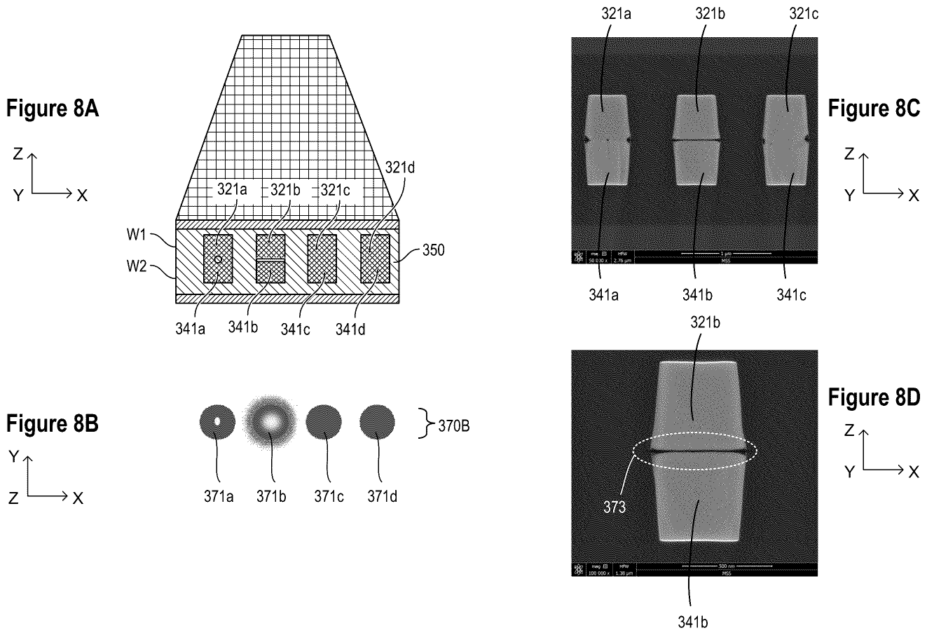

This 2D mass density or phase shift or dark field projection image, previously referred to as the hybrid bond 2D map can be transferred to a high spatial resolution pixel X-ray detector (e.g. 130) for CCD, CMOS, or sCMOS image recording and image feature extraction to optimize pre touch down alignment, post touch down verification, and hybrid bond defect detection such as voids, or other defects of interest, which will be further explained in FIGS. 8A-8D, 9A-9D and 10A-10D.

The optical train 120 and high resolution detector 130 can have unique features. The optical train 120 may include (1) a scintillator element that upconverts broad-band X-rays to a single visible light wavelength, or more preferably into the UV/blue for Lyso: Ce, or green for GGG:Ce scintillators. Many common scintillators are available, with an ideal thickness in a range of 10-50 μm, preferably 10-40 μm, preferably 20-40 μm, preferably 25-35 μm. Such a scintillator may have an optically-reflective mirror coating on the X-ray source side, and an antireflection coating facing the detector 130 to maximize optical light propagation into the forward optics and camera, removing optical light back propagation towards the X-ray source 110. The optical train 120 and the detector 130 can include (2) an objective that is infinity conjugated, has a super long working distance >25 mm, preferably >35 mm, preferably >50 mm, and has a magnification in a range of 10× to 50× with a numerical aperture NA>0.60, preferably >0.75, preferably >0.90. The optical train 120 and detector 130 can include (3) a “dog leg” or a bent path at about a 90 degree angle, between the scintillator and the objective, and the detector 130, completely preventing X-rays which are not stopped by the scintillator from entering the light optics of the objective and camera. This is a novel X-ray color center mitigation strategy that prevents severe browning of the light optical train from the objective to the detector 130, and loss of signal-to-noise ratio (SnR). Typically, optics browning may cause the light optics to be <30% transmissive, which may cause a severe impact on integrated or in-situ metrology in a matter of days or weeks, by diminishing the up-converted light signal. The detector 130 (e.g. a CCD, CMOS, sCMOS sensor) can include (4) a narrow bandpass filter for passing only the selected wavelength of the scintillator, for reducing stray light from the environment from entering the detector 130. The narrow bandpass filter can be placed after the objective within the collimated space, or where the beam is orthogonal to the narrow bandpass filter and fully collimated reducing placement errors. The detector 130 can include (5) a tube/transfer lens that refocuses the parallel optical light onto the sensor plane of camera and (6) a CCD, CMOS, or sCMOS camera with high quantum efficiency (QE) at the wavelength of detection, preferably a backside-illuminated and thinned scientific CMOS camera with >100 megapixel, and pixel sizes on the order of 2.5 μm to 5.5 μm, frame rates >300 fps for real time reporting and ROI selection, and most importantly a high bit depth (i.e. gray scale) of >16 bits for high dynamic range, and (7) an enclosure to mount the optics, and (8) a linear motor (e.g. a piezo motor) on the objective of optical train 120 to adjust remotely the best focus of the scintillator to the objective.

In some embodiments, the detector 130 includes a Peltier cooled X-ray detector, an X-ray flat panel detector, an avalanche photodiode, a photomultiplier tube, or another electrical signal device indirectly or directly converting X-rays.

In this example, the detector 130 includes a scintillator having a bent path for optical electromagnetic radiation between the scintillator and a subsequent optical imaging train including an objective, a bandpass filter, a tube lens or relay lens and/or the sensor, collectively forming a optical detector. In another example (not shown), the scintillator having a straight path to the optical detector includes color center healing or removal mechanism by selecting at least one from the group consisting of deep UV illumination or thermal heating such as UV-LEDS, UV laser driven light source, IR lamp heating, or conductive heater, such as thermal jacket or thermal wire. In yet another example (not shown), the detector 130 includes a direct conversion sensor.

In one embodiment, an X-ray image is generated by converting X-rays to fluorescent light using a scintillator in the optical train 120 or the detector 130. In another embodiment, an X-ray image is generated by direct imaging as an X-ray absorption, phase contrast, or small angle diffraction dark field image using a fully or partially transmitted signal or image. In yet another embodiment, an X-ray image is generated by phase contrast imaging, such as in-line propagation based phase contrast imaging, grating interferometry (e.g. X-ray Talbot interferometry and X-ray Talbot-Lau interferometry) and analyzer-based phase contrast imaging.

In the example of FIGS. 1A and 1B, the X-ray probe is an X-ray imaging system. In other examples (not shown), the hybrid bonding apparatus 100 may include an X-ray probe that is an X-ray non-imaging system. The X-ray non-imaging system can be configured to generate an X-ray measurement signal via at least one mechanism selected from the group consisting of X-ray diffraction, X-ray absorption, small angle X-ray scatter (SAXS), wide angle X-ray scatter (WAXS), near-edge X-ray absorption fine structure analysis (NEXAFS), X-ray near edge absorption spectroscopy (XANES), total external reflectance X-ray fluorescence (TXRF), X-ray K-edge subtraction, X-ray standing wave analysis, and X-ray reflectivity. For example, in a reflection mode of the X-ray non-imaging system, the bonder head 160 can be positioned in a measurement space disposed opposite the X-ray source 110 and a detector 130. In other words, the bonder head 160 can be positioned opposite a measurement system.

Techniques herein provide functionality that overcomes limitations observed in conventional hybrid bonders, such as common place in wafer-to-wafer bonders. There are many limitations for employing visible light or infrared (IR) imaging for global overlay alignment and defect detection at metal-to-metal interfaces. For example, a primary limitation is signal penetration. Too many layers of Si may exist and exceed the successful penetration or exit path length to extract the IR light for edge detection of fiducial marks. Moreover, optical light will not penetrate a metallic layer of copper pads, impeding buried interface measurements opposite the light source and beneath the copper pad. There can be more than two layers, but the optical strategy of measuring a topside wafer mark and bottom wafer underside mark at the circumference of the wafer cannot be easily extended to three or more wafer layers without adding a significant tolerance stack error, or the optical strategy may be completely precluded when the depth of focus (DOF) of the high numerical aperture (NA) microscopes is exceeded by an individual thickness of a die or wafer. Individual die being placed on a single substrate wafer or substrate may have no registry to the substrate/wafer fiducial marks on the circumference. The die may be placed on a film frame or tape frame without any marks altogether, or placed on a reconstituted wafer without maintaining registry (die exhibit tiling errors from die to die along any X, Y or other straight line).

Techniques herein provide the first integration of a wafer bonding process tool or die-to-wafer bonder tool that in real time pre-aligns before touch-down using an X-ray probe to provide measurement feedback data from X, Y and θ errors and minimize misplacement to near zero (within ±accuracy specification of ideally <±60 nm). Further techniques herein provide the first integration of a wafer bonding process tool or die-to-wafer bonder for hybrid bonding that in real time pre-aligns before touch-down using an X-ray probe, and then can confirm or verify the alignment after touch-down and after initiating bonding. Lastly, techniques herein provide the first integration of a wafer bonding process tool or die-to-wafer bonder for hybrid bonding that in real time pre-aligns before touch-down, verifies after touch-down, and simultaneously inspects for possible void and gap defects, foreign material, aberrant sized pads, and missing pads. Herein, the X-ray probe enables pre-align, post-verification and void, gap, foreign material, aberrant sized pads, and missing pad defect inspection. The X-ray probe can be fully integrated with the bonding head and/or function as a self-standing module or tool (e.g. a standalone X-ray probe) for post-verification and inspection.

According to some aspects of the disclosure, a hybrid de-bonding apparatus is provided. The hybrid de-bonding apparatus includes a hybrid de-bonder that has a de-bonding mechanism and is configured to de-bond a first semiconductor structure from a second semiconductor structure (mechanically, chemically, thermally, hydrostatically, vibrationally, or electrostatically). The hybrid de-bonding apparatus also includes an X-ray probe having an X-ray source and a detector. The de-bonder mechanism is integrated with the X-ray probe and positioned in a measurement gap between the X-ray source and the detector or is disposed opposite the measurement system in a reflection mode. The X-ray probe is configured to irradiate X-rays that penetrate through the first semiconductor structure and the second semiconductor structure, in whole or in part, to measure relative positions of the first semiconductor structure and the second semiconductor structure, prior to debonding. The hybrid de-bonder is configured to allow measurement of the relative alignment quality between the first semiconductor structure and the second semiconductor structure based on the relative positions of the first semiconductor structure and the second semiconductor structure.

Note that the de-bonding apparatus can be similar to the hybrid bonding apparatus 100. The descriptions have been provided above and will be omitted here for simplicity purposes.

Additionally, the hybrid bonding apparatus 100 or the de-bonding apparatus can further include an objective having a bent path of electromagnetic radiation between the scintillator and the UV-VIS light objective and the detector, to avoid transmission losses due to light optics color-center defect browning.

In some embodiments, the hybrid bonding apparatus 100 or the de-bonding apparatus further includes an objective having a straight path of electromagnetic radiation between the scintillator and the UV-VIS light objective and the detector, by integrating DUV-UV lighting to actively reverse color-center defect formation, avoiding transmission losses due to light optics browning. The color-center reversal light may be turned on when X-ray light is off at any interval, including in real-time asynchronous with the X-ray measurement.

In some embodiments, the hybrid bonding apparatus 100 or the de-bonding apparatus further includes an objective having a straight path of electromagnetic radiation between the scintillator and the UV-VIS light objective and the detector, by integrating a thermal or optical heater to actively reverse color-center defect formation, avoiding transmission losses due to light optics browning. The color-center reversal energy is supplied thermally to the objective and lens holders and may be kept on continuously or periodically to recover optical transmission.

FIG. 2 shows a flow chart of a process 200 for hybrid bonding, in accordance with one embodiment of the present disclosure. The process 200 begins with Step S210 where a first bonding surface of a first semiconductor structure is positioned at a first distance from a second bonding surface of a second semiconductor structure. The first bonding surface of the first semiconductor structure faces the second bonding surface of the second semiconductor structure. At Step S220, relative positions of the first bonding surface and the second bonding surface at the first distance are measured via an X-ray probe that includes at least one selected from the group consisting of an X-ray imaging system and an X-ray non-imaging system. At Step S230, the first bonding surface and the second bonding surface are brought closer to a second distance that is smaller than the first distance. At Step S240, the relative positions of the first bonding surface and the second bonding surface at the second distance are measured via the X-ray probe. At Step S250, relative positions of the first semiconductor structure and the second semiconductor structure are adjusted based on X-ray images of the first bonding surface and the second bonding surface. At Step S260, the first bonding surface and the second bonding surface are brought into physical contact. At Step S270, the first semiconductor structure and the second semiconductor structure are bonded via hybrid bonding.

In some embodiments, the first bonding surface and the second bonding surface are measured via the X-ray probe, and a relative bow/warp of the first bonding surface and the second bonding surface is detected and removed by applying a correction of barrel or pin cushion distortion.

In some embodiments, the first semiconductor structure includes two die, or two wafers, double the plurality of stacked die or double the plurality of stacked thinned wafers, both offset laterally from the second semiconductor structure comprised of a die or a wafer, the second structure connected overhead, or vice versa, forming a bridge between the first semiconductor structures. Techniques herein are applicable to hybrid bonding of a die to a die, a die to a wafer, a wafer to a wafer, a plurality of stacked die to a die, a plurality of stacked die to a wafer, a plurality of stacked thinned wafers to a wafer, and the like. Techniques herein utilize X-ray imaging methods and/or X-ray non-imaging methods. Hereinafter, hybrid bonding of a wafer to a wafer using an X-ray imaging method will be demonstrated for illustrative purposes only and is non-limiting.

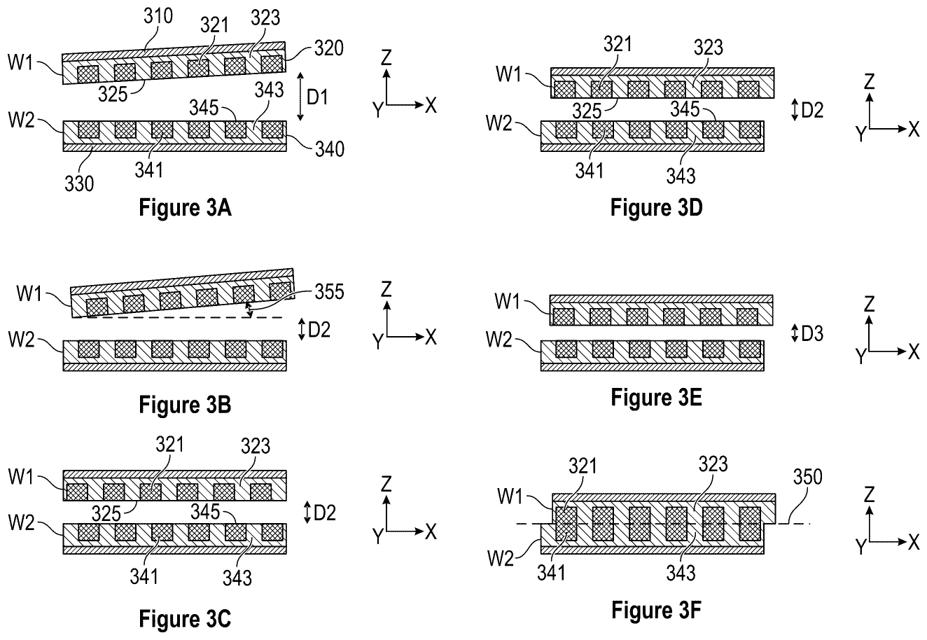

FIGS. 3A-3F show cross-sectional views of two semiconductor structures at various intermediate steps of a hybrid bonding process such as the process 200, in accordance with some embodiments of the present disclosure.

In FIG. 3A, a first bonding surface 325 of a first wafer W1 is positioned at a first distance D1 from a second bonding surface 345 of a second wafer W2. The first bonding surface 325 can directly face the second bonding surface 345. The first wafer W1 can be attached to a bonder head (not shown), such as the bonder head 160 in FIGS. 1A-1B. The second wafer W2 can be loaded, for example on a chuck or wafer holder (not shown) in the measurement gap 140 between the X-ray source 110 and the optical train 120 and the detector 130. The first wafer W1 and the second wafer W2 can be initially aligned using alignment marks (not shown) via an electromagnetic radiation-based alignment process, such as using visible light and infrared light, which may have signal penetration limitations compared with X-rays. As a result, such an initial alignment can only be considered as a coarse alignment with low precision.

Specifically, the first wafer W1 can have a first substrate 310 and a first bonding layer 320. The first bonding layer 320 can include a first hybrid metal 321, a first background dielectric 323 and the first bonding surface 325. Similarly, the second wafer W2 can have a second substrate 330 and a second bonding layer 340. The second bonding layer 340 can include a second hybrid metal 341, a second background dielectric 343 and the second bonding surface 345. While not shown, it should be understood that there may be semiconductor structures (e.g. transistors, wiring, and circuitry) already formed between the first substrate 310 and the first bonding layer 320 and already formed between the second substrate 330 and the second bonding layer 340.

In this example, the first hybrid metal 321 and the second hybrid metal 341 are Cu pads while the first background dielectric 323 and the second background dielectric 343 include a same dielectric, such as Si, SiO₂, SiN, and SiCN. The first hybrid metal 321 and the second hybrid metal 341 will also be referred to as Cu pads 321 and 341. Note that the first bonding surface 325 and the second bonding surface 345 may not be entirely flat in that the Cu pads 321 and 341 may “sink in”, i.e. be “recessed or “dished”. That is, the first background dielectric 323 and the second background dielectric 343 may be at a plane above the Cu pads 321 and 341. In another example (not shown), the Cu pads 321 and 341 may be covered by a dielectric material, such as silicon oxide. The first bonding surface 325 and the second bonding surface 345 may also be substantially flat.

In this example, the first distance D1 is defined as a distance between a first centroid of the first bonding surface 325 and a second centroid of the second bonding surface 345. Alternatively, the first distance D1 can be defined as a nearest, farthest, mean or average distance between the first bonding surface 325 and the second bonding surface 345. D1 is in a range of 3 mm to 10 mm approximately, preferably 3 mm to 7 mm, preferably 3 mm to 5 mm.

In FIG. 3B, the first bonding surface 325 and the second bonding surface 345 are brought closer to a second distance D2 that is smaller than the first distance D1. For example, the bonder head 160 can move the first wafer W1 towards the second wafer W2 while the second wafer W2 is kept stationary. D2 is in a range of 1 mm to 3 mm approximately, preferably 1 mm to 2 mm, preferably 1 mm to 1.5 mm.

Note that if the first wafer W1 and the second wafer W2 are not parallel to each other, which is often the case in practice, there is an out-of-plane angle 355 between the first bonding surface 325 and the second bonding surface 345. In other words, the first wafer W1 is tilted, relative to the second wafer W2. Consequently, when the first wafer W1 is moved towards the second wafer W2, the first wafer W1 may drift in the X-Y plane relative to wafer W2, if, for example, the cause of the out-of-plane angle 355 is non-parallel and/or misaligned bonding head axes. Such a tilt can be resolved using techniques herein, such as the X-ray imaging system including the X-ray source 110, the optical train 120 and the detector 130 in FIGS. 1A-1B.

While not shown, relative positions of the first bonding surface 325 and the second bonding surface 345 can be measured via the X-ray imaging system, both when positioned at the first distance D1 in FIG. 3A and when positioned at the second distance D2 in FIG. 3B. With relative positions measured for at least two distances, the tilt can be calculated and thus corrected for.

In FIG. 3C, the first wafer W1 is adjusted to remove the out-of-plane angle 355 and thus the tilt. Note that processes in FIGS. 3A-3C may need to be repeated and iterated to remove the out-of-plane angle 355. As a result, the first bonding surface 325 is parallel to the second bonding surface 345. The second distance D2 may remain unchanged or be slightly changed, due to the adjustment of the bonder head 160, for instance. Then, the relative positions of the first bonding surface 325 and the second bonding surface 345 can be re-measured (measured again) at the second distance D2 via the X-ray imaging system.

In FIG. 3D, in-plane alignment errors including translational misalignment and rotational misalignment can be removed based on re-measured data as discussed above. Particularly, misalignment in the X and Y directions and an in-plane angle θ (in the X-Y plane, not shown) can be removed. Consequently, each Cu pad (e.g. 321) in the first bonding layer 320 is aligned with a respective Cu pad (e.g. 341) in the second bonding layer 340. Note that in FIG. 1A, the X-ray source 110, along with the bonder head 160, can be moved and rotated to another position (e.g. 110′) to adjust to the in-plane angle θ.

In FIG. 3E, the first wafer W1 can be brought closer to the second wafer W2 to further reduce the second distance D2 to a third distance D3. Similarly, the relative positions of the first bonding surface 325 and the second bonding surface 345 can be measured at the third distance D3 to evaluate alignment between the first wafer W1 and the second wafer W2. Adjustments can be made accordingly to eliminate alignment errors.

Subsequently, the first wafer W1 can be brought closer to the second wafer W2 to further reduce the third distance D3 to a fourth distance, and then to a fifth distance . . . as needed. Every time the first bonding surface 325 and the second bonding surface 345 are positioned at a smaller distance, the relative positions of the first bonding surface 325 and the second bonding surface 345 can be measured to make adjustments to eliminate alignment errors. As a result, as the first wafer W1 and the second wafer W2 are moved closer and closer to each other, such a move-measure-adjust process can be done in real time iteratively and repeatedly until the first bonding surface 325 and the second bonding surface 345 come into physical contact with each other, as shown in FIG. 3F. The first wafer W1 and the second wafer W2 can be bonded to each other via a bonding interface 350 by a hybrid bonding process.

In the examples of FIGS. 3A-3F, the first hybrid metal 321 and the second hybrid metal 341 are Cu pads while the first background dielectric 323 and the second background dielectric 343 include the same dielectric, such as Si, SiO₂, SiN, and SiCN. Accordingly, direct copper to copper bonding is used to bond the first background dielectric 323 and the second background dielectric 343. Both the first hybrid metal 321 and the second hybrid metal 341 and the first background dielectrics 323 and the second background 343 are simultaneously bonded using a stress-free low temperature variant of thermocompression bonding (also known as direct bonding or hybrid bonding) at room temperature or elevated temperature in the range from 40 degrees C. to 200 degrees C. Moreover, the Cu pads (e.g. 321 and 341) are typically treated to promote low temperature bonding; for instance, the Cu pads (e.g. 321 and 341) may be coated with proprietary wetting or passivation layers that promote Cu diffusion, and inhibit AuCu₃ formation and Cu oxidation, or alternatively may be ion beam activated at low landing energies, such as using Ar ions at 40-100 eV range, or by using a special phase of Cu such as the combination of nanotwinned Cu with thin SiO₂ with modified morphology such as tuned dishing shape.

In other examples, the first wafer W1 and the second wafer W2 can be bonded by other wafer bonding techniques, such as surface-activated bonding, plasma-activated bonding, anodic bonding, eutectic bonding, glass frit bonding, adhesive bonding, reactive bonding, transient liquid phase diffusion bonding, and/or the like. Accordingly, the first bonding layer 320 and the second bonding layer 340 may include one or more different hybrid metals and/or one or more different background dielectrics from each other.

As discussed earlier, the hybrid bonding of the first wafer W1 to the second wafer W2 are demonstrated for illustrative purposes only and is non-limiting. Techniques herein are applicable to hybrid bonding of a die to a die, a die to a wafer, a wafer to a wafer, a plurality of stacked die to a die, a plurality of stacked die to a wafer, a plurality of stacked thinned wafers to a wafer, and the like. Particularly, to enable advanced packaging schemes such as “chiplets”, die-to-wafer (D2 W) hybrid bonding, also referred to as chip-to-wafer (C2 W) hybrid bonding, is often implemented. For example, the D2 W hybrid bonding is applicable to HPC and CPU/GPU applications, in addition to memory die stacking for HBM. The descriptions above for wafer-to-wafer (W2 W) hybrid bonding are also applicable to D2 W or C2 W hybrid bonding and will be omitted herein for simplicity purposes.

FIG. 4 shows a flow chart of a process 400 for hybrid bonding, such as that shown in FIGS. 3A-3F. The process 400 starts with Step S410 where a substrate wafer (e.g. the second wafer W2) can be loaded into a chuck of a hybrid bonder and aligned using alignment marks on the substrate wafer and the chuck of the hybrid bonder. The substrate wafer is a patterned wafer that has transistors, wiring and/or circuitry. At Step S420, another wafer (e.g. the first wafer W1) is picked and placed using alignment marks on the substrate wafer and the another wafer. The another wafer can be attached to a bonder head of the hybrid bonder. For illustrative purposes, the substrate wafer and the another wafer will be respectively referred to as the second wafer W2 and the first wafer W1 hereinafter.

At Step S431, the first wafer W1 can move in the Z direction and thus be positioned at at least two different heights Z1 and Z2, relative to the second wafer W2. For instance, the first wafer W1 can be moved in the Z direction by the bonder head so as to have different distances (e.g. D1 and D2) from the second wafer W2. At Step S433, relative positions of the first wafer W1 and the second wafer W2 can be measured for both Z1 and Z2 via the X-ray imaging system in FIGS. 1A-1B and used to derive alignment mark error vectors between the first wafer W1 and the second wafer W2. The relative positions can contain information in the X direction and the Y direction as well as about the in-plane angle θ and the out-plane angle (e.g. 355). At Step S435, tilt or tip between the first wafer W1 and the second wafer W2 can be removed using the relative positions of the first wafer W1 and the second wafer W2 at both Z1 and Z2. For example, wafer Z-height piezo actuators can be adjusted, or alternatively relative movement by the stage holding second wafer W2 with respect to first wafer W1 can be used, or vice versa.

Note that Steps S431, S433 and S435 can be repeated and iterated until the tilt between the first wafer W1 and the second wafer W2 is adjusted to below a threshold value so that the tilt is considered to have been removed. Additionally, Steps S431, S433 and S435 are not necessarily executed sequentially and may be executed partially or wholly in tandem. For instance, the relative positions of the first wafer W1 and the second wafer W2 can be measured every time the first wafer W1 is moved in the Z direction.

At Step S441, the relative positions of the first wafer W1 and the second wafer W2 are measured for a single height, such as Z2. At Step S443, the first wafer W1 and/or the second wafer W2 are then adjusted to remove in-plane alignment errors e.g. in the X and Y directions and the in-plane angle θ. In some embodiments, Steps S441 and S443 are repeated and iterated until the in-plane alignment errors between the first wafer W1 and the second wafer W2 are adjusted to below threshold values. For example, the first wafer W1 can be gradually brought closer to the second wafer W2 to reduce the height (or distance). For each height, the relative positions of the first wafer W1 and the second wafer W2 are measured to remove the in-plane alignment errors. In some embodiments, Steps S431, S433 and S435 can be executed to remove both out-of-plane alignment errors and in-plane alignment errors. Then, the first wafer W1 is gradually brought closer to the second wafer W2 to reduce the height.

At Step 450, the first wafer W1 and the second wafer W2 are brought into physical contact and bonded to each other by hybrid bonding to form a bonded structure, for example by fusion bonding of both background dielectrics and hybrid metals, activated or coated, using low-temperature thermocompression bonding (TCB) of hybrid metals. Bonding initiates upon physical contact and is completed by heating in the temperature range from room temperature (RT) to <200 degrees C., while under pressure. At Step S460, the X-ray imaging system can be used to measure the bonded structure to validate bonding and inspect for bonding defects, if there are any.

At Step S470, bonding results obtained at Step S460 are reported and recorded into a semiconductor fab ledger via SECSGEM/SECS300 and maintained in a local database, which can be used to guide future hybrid bonding from run to run, that day, week to week, month to month, and across the production line's useful life. In one embodiment, the process 400 returns to Step S420 by picking and placing another die or wafer on the substrate wafer. In another embodiment, the process 400 returns to Step S410 by loading and aligning a new substrate wafer.

In a non-limiting example, methods for pre-touch down measurement and adjustment include using pad features (e.g. Cu pads) on the first wafer W1 in unison with pad features (e.g. Cu pads) on the second wafer W2 (or thinned wafer features in the multi stack of wafers with substrate wafer or film frame) when there is an air gap (for example as represented by the first distance D1) but the opposing pads (e.g. 321 and 341) are in close proximity. X-rays project through all the layers including metal, and generate thickness-projection for absorption, or phase contrast change, or dark field small angle scatter, either imaging modality in its singular form or in a combined form being used to form the hybrid bond 2D map or hybrid bond 2D contrast map. The center-to-center misalignment is calculated using generalized image features such as blob analysis, or other pattern recognition based on fitted functions of the features such as using moment features such as centroids for all the features of interest, and X, Y and θ can be quantitatively generated from the large number of features extracted. This can be accomplished using a statistical distribution and determining a center of intersection, such as a mean or median, or equivalent distribution measure of center of mass or gravity or higher order moments to define the tail and head of a vector, with both a direction and magnitude. For instance, two, or three, or more regions of features for the first wafer W1 and the second wafer W2 can define a vector in the Y direction and a vector in the X direction for adjacent features in the second wafer e.g. alignment marks, and similarly in the first wafer in the X′ direction and in the Y′ direction. Multiple adjustments in the second wafer W2 can be made relative to the bonding head to overlap the X with X′ and Y with Y′, or vice versa in W1 relative to W2. And small perturbations (or small movements) in z movement can be made as the first wafer W1 performs an approach move towards contact (e.g. Cu pads in the second wafer W2). Each perturbation can be in a range of 0.1 to 3 mm, preferably 0.1 to 2 mm, preferably 0.1 to 1 mm. X (for the second wafer W2) and X″ (for the first wafer W1 during the approach move), and Y (for the second wafer W2) and Y″ (for the first wafer W1 during the approach move) can be aligned to account for systematic tool to tool variation, multi head on single tool variation, and wafer and wafer dependent tip/tilt errors (wafer TTV, wafer bow/warp, thinning artifacts, roll-off, large height variations due to metallization/CMP, film growth TTV, etc.). This strategy of measure, correct, and z movement of wafer(s) can be applied iteratively until the first wafer W1 touches down on the second wafer W2. Then, post bond initiation, assuming all bond head parameters were met for optimized contact (temperature, pressure, time, point of contact, etc.), the hybrid bond 2D contrast map is re-taken to observe any bonding head-induced slide or misorientation. And the wafer final values are logged in an electronic map or EMAP to be passed to factory host over SECSGEM/SECS300 and/or saved in a local database, along with wafer location and degree of X, Y and θ misalignment relative to the wafer datum (e.g. the second wafer W2), and the total integrated ionizing dose delivered for dose history tracking and certification. The latter data can be uploaded as a 0/1 binary pass/fail map, or be clustered to partition into bins based on degree of misalignment, the pass/fail or binned data may be sent to a subsequent processing tool or may be fed forward to the next step in the same hybrid bonder using the local database or factory host SECSGEM/SECS300 protocols. The process 400 can be performed for every die on wafer, or every cell from a multitude of wafers or die on a film frame.

Aspects of the present disclosure relate to a stack of multiple die (e.g. 16 high, or 16H, or more) and disclose a unique alignment target that is printed along with the hybrid bond pads and does not add any additional processing steps, as shown in FIGS. 5A-5B. FIG. 5A shows a schematic of a bonded structure 500A in conventional technologies. FIG. 5B shows a schematic of a bonded structure 500B in accordance with one embodiment of the present disclosure.

Herein, each die has a “domino” of four solid circles (the same Cu pads as the hybrid pads e.g. 321 and 341), and the four solid circles exist on an outer edge of a die 520 (e.g. 520a, 520b and 520c) and within each cell of a substrate wafer 510 underneath (chip cell on wafer locations, typically 600 for CoW). Going from bottom to topmost, the domino of four circles is offset with generalized X and Y error vectors, per die. A first die 520a aligns closest to the substrate wafer 510. A pattern 511 of four circles of the substrate wafer 510 and the resulting error vectors are shown for the first three die (e.g. 520a, 520b and 520c) in FIG. 5A. The alignment is simplified because the center or centroid of all the circles defines the metrology vector for each layer along the X and Y directions. Here the substrate wafer 510 can be adjusted with respect to the first die 520a until all the vectors align without an angle or offsets with respect to X and Y. Alternatively, the first die 520a can be adjusted relative to the substrate wafer 510. Additionally, the tip tilt can be removed prior to applying corrections as described in FIGS. 2, 3A-3F and 4. Next, such a process is repeated for a second die 520b, a third die 520c and so forth, with respect to the substrate wafer 510, and all the way to the topmost die minimizing the total tolerance stack error. It is understood that the domino shape, number of circles in the domino, and the choice of shape as a circle is not a limitation of the approach. In other words, other distributions that don't represent dominos, for instance conventional cross-hairs, triangles, squares, interdigitated patterns, 1D or 2D data matrices to ID a given layer with respect to the substrate, may all be used. Additionally, the contrast may be adjusted by adjusting size, thickness, and fill ratio of metallization for the alignment fiducials and features, without loss of general applicability.

An example of removing the error for the first three die is shown in FIG. 5B using techniques described herein. In all cases, pattern recognition is applied to adjust the X and Y offsets to achieve alignment to within ±60 nm (edge detection or centroid detection can enable alignment within 1/10th of the projected pixel size for the given magnification in the range from 2 to 20×, approximately, preferably 4×, thus deriving a 0.6 μm projected pixel size onto the die and wafer, or 1/10^{th} of 0.6 μm being 60 nm). The novelty of the X-ray source 110 allows penetration of all die in which all the metal pads used for alignment targets are buried in the wafer and can be found to reference the underlying die and wafer. A 70 keV X-ray can penetrate tens of millimeters of silicon without issue, and approximately 3 mm of Cu with ample X-ray transmission signal. The final alignment marks for all die will look like an evenly spaced ladder of dominos with four circles per die. Again, the individual error vectors for X and Y between a die 520 and the substrate wafer 510 or between layers (e.g. die to die) can be calculated along with the deviation angle and errors removed. The benefit of using the lithography and CMP layers of the hybrid bond pad is that no additional mask or metallization or CMP step need to be added. Moreover, it enables having very complex RDL on substrate, BEOL metal M1-MXX, and FEOL Finfets or GAA or CFET transistors in each stacked die and not having overlap confusion in the hybrid bond 2D contrast map features used for alignment, as the domino-shaped fiducials are outside the area of the active device in a clear street or scribe line. Lastly, the offset of the domino fiducials enables a single top-down image to be used in bonding each layer and during final verification of alignment, enabling extremely fast throughput without overdosing with X-rays, and without applying multiple tilts to the X-ray source as is typically done with 3D CT or production line 2D oblique view X-ray microscopes.

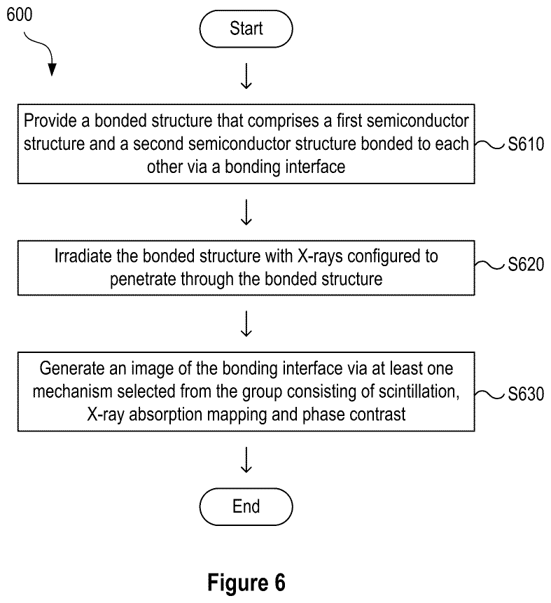

FIG. 6 shows a flow chart of a process 600 for bonding inspection, in accordance with one embodiment of the present disclosure. The process 600 begins with Step S610 by providing a bonded structure that includes a first semiconductor structure and a second semiconductor structure bonded to each other via a bonding interface. At Step S620, the bonded structure is irradiated with X-rays that are configured to penetrate through the bonded structure. At Step S630, an image of the bonding interface is generated via at least one mechanism selected from the group consisting of scintillation, X-ray absorption mapping and phase contrast, dark field small angle scatter, and non-imaging X-ray detection.

In some embodiments, an interface defects at the bonding interface (e.g. 350) can include, but is not limited to, a void (e.g. a pin hole), a gap (e.g. unbonded metal pads and unbonded dielectrics), a crack (e.g. delamination), a trapped particle (e.g. foreign material), an aberrant size pad, a wholly missing Cu pad, misalignment, etc. The void, gap, or crack can be vacuum, or may include trapped air, or be partially filled with metal or organic encapsulation, or other diffused nearby materials. A post-bonding inspection can be performed using the X-ray imaging system to perform defect detection in the metal-to-metal (e.g. 321 and 341) hybrid bonding interfaces or improper bonding at the dielectric (e.g. 323 and 343) interface. A substantially collimated light supplies spatially coherent light which will enter the metal-to-metal interface when using an X-ray capillary (e.g. 114) or (not shown) a large array of precisely located X-ray emitters derived from using one of the following: a polycapillary, a metal absorbing or phase shifting grating (1D, or 2D), a flat panel array of multiple electron emitter sources onto a patterned anode, or a single electron emitter onto a patterned anode. If there is a small gap at the bonding interface 350, whether horizontal or vertical with respect to an incident beam (e.g. 115), the small scatter angle of the low divergence beam (e.g. 115) will undergo total external reflection in the air or vacuum gap at the hybrid bonded interface (e.g. 350), whether it is dielectric or metal, or any size void. This gap will show up with forward focused intensity and appear highlighted in the hybrid bump 2D image (e.g. 371b in FIG. 8B). Alternatively, the spatially coherent wavefront transmitted through the bonding interface may self-interfere to obviate a phase difference in void regions of metal to metal contact or dielectric to dielectric contact (i.e. create a different phase object), allowing application of Lau, Talbot, or Talbot-Lau X-ray grating interferometric techniques where the metal to metal bonded pads take the place of G1 or G2 phase or analyzer grating, or are included as the object between the G1 and G2 gratings. Moreover, if the void size is on the order of 25% to 50% of the projected pixel size (e.g. in a range of 0.2-3 μm), machine learning can identify its presence by comparing nearby regions of equal design (found through clustering, defined in the recipe, or selected from 3D1 gerber file, or chip GDSII file). A pin hole defect of this type is shown in FIG. 8B (see e.g. 371a). For instance, a difference image will identify a void defect location when voting across two or more comparisons with its nearest neighbor regions. If the void is larger than the pixel size, the void diameter or volume can be quantitatively calculated, and calibrated against physical cross section in X-SEM, P-lapping, or TEM. The dielectric roll-off near high metal features leading to incomplete bonding near alignment targets may also be quantified in similar means.

FIG. 7A shows a schematic of bonding inspection, FIG. 7B shows a schematic of a bonded structure, and FIGS. 7C and 7D show cross-sectional views of a bonded structure, in accordance with some embodiments of the present disclosure. As shown, an X-ray beam 360 (e.g. the X-ray beam 115) is projected to image the bonding interface 350 between the first wafer W1 and the second wafer W2, for example by the X-ray imaging system in FIGS. 1A-1B. As a result, an X-ray image 370A is generated, for instance as a hybrid bond 2D map, or projection thickness 2D map, or phase contrast 2D map (phase shift highlight or interferometric fringe difference in phase), or dark field small angle scatter 2D map.

In this example, the first wafer W1 and the second wafer W2 are aligned with each other with no alignment error and bonded to each other with no bonding defect, as shown in electron microscopy images in FIGS. 7C and 7D. Therefore, the X-ray image 370A includes an array of solid dots 371.

FIG. 8A shows a schematic of bonding inspection, FIG. 8B shows a schematic of a bonded structure, and FIGS. 8C and 8D show cross-sectional views of a bonded structure, in accordance with some embodiments of the present disclosure.

Herein, Cu pads 321a, 321b, 321c and 321d are respectively aligned with Cu pads 341a, 341b, 341c and 341d with no alignment error. Cu pads 321c and 321d are respectively bonded to Cu pads 341c and 341d with no bonding defect. Accordingly, an X-ray image 370B includes two solid dots 371c and 371d. However, there is a void or pinhole between Cu pads 321a and 341a, thus a heterogeneous dot 371a in the X-ray image 370B, which is a solid dot with a central pinhole. Additionally, there is a gap 373 (e.g. an air or vacuum gap) between Cu pads 321b and 341b. Therefore, a heterogeneous dot 371b appears highlighted with forward focused intensity in the X-ray image 370B, which is caused by total external reflection in the gap 373, as discussed above. Alternatively, the interferometric X-ray using Lau, Talbot, or Talbot-Lau configurations would lead to fringe differences due to the phase shift caused by self-interference due to the phase-changing object (solid metal versus metal with the void).

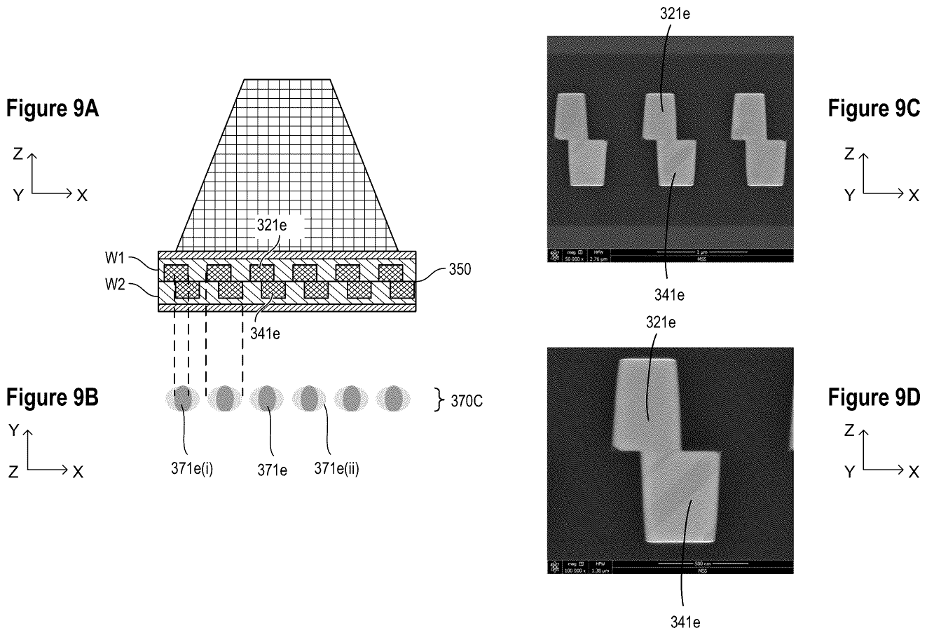

FIG. 9A shows a schematic of bonding inspection, FIG. 9B shows a schematic of a bonded structure, and FIGS. 9C and 9D show cross-sectional views of a bonded structure, in accordance with some embodiments of the present disclosure.

Herein, each Cu pad 321e of the first wafer W1 is misaligned or staggered with a respective Cu pad 341e of the second wafer W2. As a result, an X-ray image 370C includes an array of heterogeneous dots 371e, each of which includes a respective middle portion 371e (i) and two respective side portions 371e (ii). Each middle portion 371e (i) has a different color or brightness from the two respective side portions 371e (ii), which is caused by different absorption or transmission of X-rays and varying degrees of phase shift/fringe interference, and varying degrees of small angle scatter or dark field, due to different amounts of metal and dielectric in the Z direction causing different phase objects and varying thickness in the X-ray beam direction. Otherwise, each Cu pad 321e is bonded to a respective Cu pad 341e with no void or gap defect.

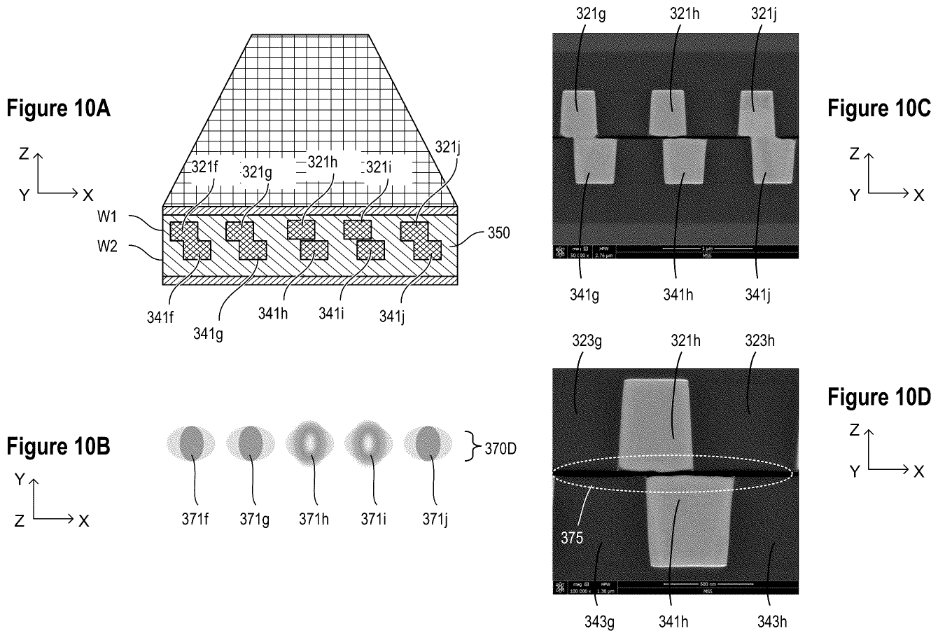

FIG. 10A shows a schematic of bonding inspection, FIG. 10B shows a schematic of a bonded structure, and FIGS. 10C and 10D show cross-sectional views of a bonded structure, in accordance with some embodiments of the present disclosure.

Herein, Cu pads 321f, 321g, 321h, 321i and 321j are respectively misaligned or staggered with Cu pads 341f, 341g, 341h, 341i and 341j. As a result, an X-ray image 370D includes an array of heterogeneous dots 371f, 371g, 371h, 371i and 371j, each of which includes a respective middle portion and two respective side portions having color or brightness contrast. Cu pads 321f, 321g and 321j are respectively bonded to Cu pads 341f, 341g and 341j with no bonding defect. Cu pads 321h and 321i are respectively bonded to Cu pads 341h and 341i with a respective gap. Therefore, the heterogeneous dots 371h and 371i appear highlighted with forward focused intensity, similar to the heterogeneous dot 371b, indicating a different phase object. Additionally, a crack 375 not only exists between the Cu pads 321h and 341h, but also extends between neighboring dielectrics 323g and 343g as well as 323h and 343h. In other words, delamination occurs in this area, also presenting a different phase object for the transmitting X-ray wavefront.

While Cu pads are used as an example for illustrative purposes in FIGS. 7A-7D, 8A-8D, 9A-9D and 10A-10D, it should be understood that other metal materials can also be used for hybrid bonding, as well as portions of redistribution lines or Cu filled vias. Solid dots (e.g. 371c and 371d) and heterogeneous dots (e.g. 371a, 371b, 371e and 371h) are shown herein. It should be understood that the Cu pads 321 and 341 may have any other shapes by design.

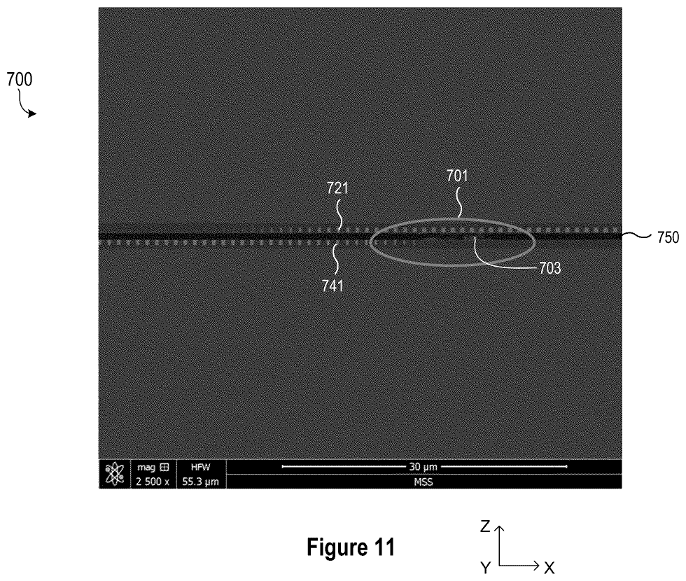

FIG. 11 shows a cross-sectional view of a bonded structure 700. As shown, the bonded structure 700 includes hybrid metals 721 and 741. However, in an area 701, there is foreign material 703 at a bonding interface 750, which impedes good bonding and can be detected as a phase object change through phase contrast imaging (phase change highlighted or interferometric fringe differences approach) or as an enhancement of small angle scatter in dark field imaging.

The various embodiments described herein offer many advantages. For example, techniques herein provide an X-ray probe that can penetrate many die layers and metallization layers that will be used for 3D1. Techniques here can be optimized to detect defects in dielectrics over metal, and vice versa, by choosing an appropriate imaging modality and energy of X-ray analysis. Techniques herein utilize the full X-ray penetration of all the metal Cu pads to produce X-ray metrology vectors to remove X, Y and θ misalignments and offsets between layers and the substrate, using a single datum. Techniques herein offer the first close loop feedback X-ray metrology as part of a hybrid bonding tool to enhance placement accuracies down to <±60 nm or 1/10th of the X-ray probe projected pixel resolution under detector and/or X-ray projection magnification. Techniques herein enable the first alignment correction prior to hybrid bonding to avoid re-work or yield loss by using X-rays. Techniques herein provide the first combined or integrated pre-align and post-align verification, and void detection method for hybrid bonding, which can be used for applications where the number of Si layers is >16 (e.g. in high bandwidth memory stacks of die) or where the total Cu metallization thickness exceeds 1 mm. Techniques herein provide the first X-ray probe method to find hybrid bonding misalignment after bonding and feed forward EMAPs to the hybrid bonder of known good die and bad die sites for subsequent bonding, such as a multi-die stack recipe to avoid adding expensive KGD to a badly misplaced underlying die. Aspects of the present disclosure provide the first X-ray technique to achieve 60 nm placement accuracies without using optical light or IR or using difficult-to-fabricate within-scribeline gratings such as those used by OCD and CD SAXS designed for grating based alignment on 10-25 μm sized pads, and which preclude the use of the in-die circuit elements or 3D1 pad elements for alignment. Aspects of the present disclosure provide the first X-ray technique to inspect hybrid bond defects in real time as the bonder performs bonding. Aspects of the present disclosure provide a device that can use a capillary tube integrated with the bonder head to guide the X-rays down through the die as the hybrid bonder bonds (e.g. D2 W die-to-wafer, W2 W wafer-to-wafer, stacked D2 W stacked-dies-to-wafer, or stacked W2 W stacked-wafers-to-wafer). Alternatively, the phase coherent source can be guided or unguided with any generalized array of precisely located 1D or 2D X-ray spots to achieve spatial coherence, including but not limited to a multitude of laser spots focused onto liquid anodes resulting in high brilliance X-ray emission spots, an array of micropatterned CNTs in 1D or 2D hitting a metal target to form X-ray spots, an array of 1D or 2D electron emitters matched to an array of metal anodes in either solid or liquid form to form X-ray spots, a single large area electron emitter, such as a dispenser cathode, cold field emitter, or photocathode focused onto an array of metal anodes in either solid or liquid form to form X-ray spots, or a group of single monocapillary or polycapillary focusing or collimating devices to generate an aggregate of spatially coherent X-ray spots.

Example embodiments of the invention are described below. Other embodiments can also be understood from the entirety of the specification as well as the claims filed herein.

Example 1. A method of hybrid bonding, the method comprising: positioning a first bonding surface of a first semiconductor structure at a first distance from a second bonding surface of a second semiconductor structure, wherein the first bonding surface of the first semiconductor structure faces the second bonding surface of the second semiconductor structure; measuring relative positions of the first bonding surface and the second bonding surface at the first distance via an X-ray diagnostic system; bringing the first bonding surface and the second bonding surface closer to a second distance that is smaller than the first distance; measuring the relative positions of the first bonding surface and the second bonding surface at the second distance via the X-ray diagnostic system; adjusting relative positions of the first semiconductor structure and the second semiconductor structure based on at least one X-ray signal measured from the first bonding surface and the second bonding surface; bringing the first bonding surface and the second bonding surface into physical contact; and bonding the first semiconductor structure and the second semiconductor structure via hybrid bonding.

Example 2. The method of Example 1, wherein the X-ray diagnostic system is configured to irradiate X-rays that penetrate through the first semiconductor structure and the second semiconductor structure.

Example 3. The method of Example 1, wherein the X-ray diagnostic system comprises an X-ray imaging system or a non-imaging X-ray measurement system.

Example 4. The method of Example 1, wherein the X-ray diagnostic system is an X-ray imaging system configured to generate X-ray images of the first bonding surface and the second bonding surface via at least one imaging method selected from the group consisting of scintillation, direct X-ray imaging, X-ray absorption imaging, X-ray phase contrast imaging, X-ray interferometric fringe difference imaging, and small angle scatter (dark field) imaging.

Example 5. The method of Example 1, wherein the X-ray diagnostic system is a non-imaging X-ray measurement system configured to generate at least one X-ray measurement signal related to the first bonding surface and the second bonding surface via at least one X-ray diagnostic method selected from the group consisted of X-ray diffraction, X-ray absorption, X-ray SAXS and X-ray WAXS in reciprocal space (small and wide angle X-ray scatter), near edge X-ray absorption fine structure analysis (NEXAFS), X-ray near edge absorption spectroscopy (XANES), total external reflectance X-ray fluorescence (TXRF), X-ray K-edge subtraction, X-ray standing wave analysis, and X-ray reflectivity measurement.

Example 6. A method of bonding inspection, the method comprising: providing a bonded structure that comprises a first semiconductor structure and a second semiconductor structure bonded to each other via a bonding interface; irradiating the bonded structure with X-rays configured to penetrate through the bonded structure; and generating X-ray measurement of the bonding interface via at least one X-ray diagnostic method selected from the group consisting of X-ray diffraction, X-ray absorption, X-ray SAXS and X-ray WAXS in reciprocal space (small and wide angle X-ray scatter), near edge X-ray absorption fine structure analysis (NEXAFS), X-ray near edge absorption spectroscopy (XANES), total external reflectance X-ray fluorescence (TXRF), X-ray K-edge subtraction, X-ray standing wave analysis, and X-ray reflectivity measurement.

Example 7. The method of Example 6, further comprising: performing defect analysis, with the image of the bonding interface, of at least one interface defect selected from the group consisting of a void, a gap, delamination, foreign material, a crack, aberrant copper pad size, a missing pad, and misalignment.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of hybrid bonding, the method comprising:
positioning a first bonding surface of a first semiconductor structure at a first distance from a second bonding surface of a second semiconductor structure, wherein the first bonding surface of the first semiconductor structure faces the second bonding surface of the second semiconductor structure;
measuring relative positions of the first bonding surface and the second bonding surface at the first distance via an X-ray probe;
bringing the first bonding surface and the second bonding surface closer to a second distance that is smaller than the first distance;
measuring the relative positions of the first bonding surface and the second bonding surface at the second distance via the X-ray probe;
adjusting relative positions of the first semiconductor structure and the second semiconductor structure based on X-ray images of the first bonding surface and the second bonding surface;
bringing the first bonding surface and the second bonding surface into physical contact; and
bonding the first semiconductor structure and the second semiconductor structure via hybrid bonding.

2. The method of claim 1, further comprising:
analyzing a bonding interface between the first semiconductor structure and the second semiconductor structure via the X-ray probe after the hybrid bonding.

3. The method of claim 2, further comprising:
performing defect analysis, via the X-ray probe, of at least one interface defect selected from the group consisting of a void, a gap, delamination, foreign material, a crack, aberrant copper pad size, a missing pad, and misalignment.

4. The method of claim 1, wherein adjusting the relative positions of the first semiconductor structure and the second semiconductor structure comprises:
removing out-of-plane tilt based on the relative positions of the first bonding surface and the second bonding surface at the first distance and at the second distance so that the first bonding surface and the second bonding surface are parallel to each other.

5. The method of claim 4, further comprising:
removing at least one in-plane misalignment selected from the group consisting of a translational misalignment and a rotational misalignment.

6. The method of claim 5, further comprising:
after removing the out-of-plane tilt, re-measuring the relative positions of the first bonding surface and the second bonding surface at the second distance via the X-ray probe; and
removing the at least one in-plane misalignment based on the re-measuring.

7. The method of claim 5, further comprising:
after removing the out-of-plane tilt misalignment, bringing the first bonding surface and the second bonding surface closer to a third distance that is smaller than the second distance;
measuring the relative positions of the first bonding surface and the second bonding surface at the third distance via the X-ray probe; and
removing the at least one in-plane misalignment based on the relative positions of the first bonding surface and the second bonding surface at the third distance.

8. The method of claim 4, further comprising:
removing at least one relative distortion from the group consisting of a barrel distortion and a pin cushion distortion.

9. The method of claim 1, further comprising:
measuring the relative positions of the first bonding surface and the second bonding surface via the X-ray probe in real time.

10. The method of claim 9, further comprising:
(a) bringing the first bonding surface and the second bonding surface closer to a smaller distance;
(b) adjusting the relative positions of the first semiconductor structure and the second semiconductor structure, based on real-time X-ray images or real-time non-imaging X-ray measurement signals of the first bonding surface and the second bonding surface at the smaller distance; and
repeating (a) and (b) until the first bonding surface and the second bonding surface are brought into physical contact.

11. The method of claim 1, wherein:
the X-ray probe is configured to irradiate X-rays that penetrate, in whole or in part, through the first semiconductor structure and the second semiconductor structure.

12. The method of claim 11, wherein:
the X-ray probe includes at least one selected from the group consisting of an X-ray imaging system and an X-ray non-imaging system, where
the X-ray imaging system is configured to generate images of the first bonding surface and the second bonding surface via at least one mechanism selected from the group consisting of scintillation, direct imaging of X-rays, X-ray absorption imaging, X-ray phase contrast imaging, X-ray interferometric fringe difference imaging, and small angle scatter dark field imaging, and
the X-ray non-imaging system is configured to generate an X-ray measurement signal via at least one mechanism selected from the group consisting of X-ray diffraction, X-ray absorption, small angle X-ray scatter (SAXS), wide angle X-ray scatter (WAXS), near-edge X-ray absorption fine structure analysis (NEXAFS), X-ray near edge absorption spectroscopy (XANES), total external reflectance X-ray fluorescence (TXRF), X-ray K-edge subtraction, X-ray standing wave analysis, and X-ray reflectivity.

13. The method of claim 1, further comprising:
loading and aligning the second semiconductor structure into a measurement space,
attaching the first semiconductor structure to a bonder head of a hybrid bonder; and
aligning the first semiconductor structure and the second semiconductor structure with alignment marks via an electromagnetic radiation other than X-rays.

14. The method of claim 13, wherein:
the measurement space is a measurement gap between an X-ray source of the X-ray probe and a detector of the X-ray probe or is disposed opposite the X-ray source of the X-ray probe and opposite the detector of the X-ray probe.

15. The method of claim 1, wherein:
the first semiconductor structure includes a die, a wafer, a plurality of stacked dies or a plurality of stacked thinned wafers; and
the second semiconductor structure includes a die or a wafer.

16. A method of bonding inspection, the method comprising:
providing a bonded structure that comprises a first semiconductor structure and a second semiconductor structure bonded to each other via a bonding interface;
irradiating the bonded structure with X-rays configured to penetrate through the bonded structure; and
generating an X-ray image or an X-ray measurement signal of the bonding interface via at least one mechanism selected from the group consisting of scintillation, direct imaging of X-rays, X-ray absorption imaging, X-ray phase contrast imaging, X-ray interferometric fringe difference imaging, small angle scatter dark field imaging, X-ray diffraction, X-ray absorption, small angle X-ray scatter (SAXS), wide angle X-ray scatter (WAXS), near-edge X-ray absorption fine structure analysis (NEXAFS), X-ray near edge absorption spectroscopy (XANES), total external reflectance X-ray fluorescence (TXRF), X-ray K-edge subtraction, X-ray standing wave analysis, and X-ray reflectivity.

17. The method of claim 16, further comprising:
performing defect analysis, with the X-ray image or the X-ray measurement signal of the bonding interface, of at least one interface defect selected from the group consisting of a void, a gap, delamination, foreign material, a crack, aberrant copper pad size, a missing pad, and misalignment.

18. A hybrid bonding apparatus, comprising:
a hybrid bonder comprising a bonder head and configured to bond a first semiconductor structure to a second semiconductor structure via hybrid bonding; and
an X-ray probe comprising an X-ray source and a detector,
wherein the bonder head is positioned in a measurement gap between the X-ray source and the detector or positioned in a measurement space opposite to both the X-ray source and the detector,
wherein the X-ray probe is configured to irradiate X-rays that penetrate through the first semiconductor structure and the second semiconductor structure, in whole or in part, to measure relative positions of the first semiconductor structure and the second semiconductor structure,
wherein the hybrid bonder is configured to align the first semiconductor structure and the second semiconductor structure based on the relative positions of the first semiconductor structure and the second semiconductor structure.

19. The hybrid bonding apparatus of claim 18, further comprising:
an objective having a bent path for optical electromagnetic radiation between a scintillator of the detector and a subsequent optical imaging train selected from the group consisting of an objective, a bandpass filter, a tube lens or relay lens, and a sensor.

20. The hybrid bonding apparatus of claim 18, further comprising:
a hybrid de-bonder,
wherein the de-bonder is configured to measure misalignment between the first semiconductor structure and the second semiconductor structure based on the relative positions of the first semiconductor structure and the second semiconductor structure.

21. The hybrid bonding apparatus of claim 20, wherein the X-ray source is spatially coherent and comprises at least one of a single monocapillary, a single polycapillary, a 1D or 2D array of monocapillaries, a 1D or 2D array of polycapilliaries, a 1D or 2D array of X-ray spots, a 1D or 2D array of laser spots focused onto a stream of liquid anodes or array of liquid anodes, a 1D or 2D array of micropatterned carbon nanotubes (CNTs) interacting with a metal target to form an array of X-ray spots, a 1D or 2D array of electron emitters matched to an array of solid or liquid metal anodes to form a 1D or 2D array of X-ray spots, a dispenser cathode large area electron emitter or a cold field large area electron emitter or a photocathode large area electron emitter focused onto a 1D or 2D array of solid or liquid metal anodes to form a ID or 2D array of X-ray spots,
wherein a moncapillary or policapillary is of the focusing or collimating type.
